(19) United States
(12) Patent Application Publication
(10) Pub. No.: US 2025/0349509 A1
(43) Pub. Date: Nov. 13, 2025

(54) METHODS AND APPARATUS THAT USE INDUCTIVELY COUPLED PLASMA RESONATOR SOURCES

(71) Applicant: Applied Materials, Inc., Santa Clara, CA (US)

(72) Inventors: Zhimin JIANG, Santa Clara, CA (US); Yuhui ZHANG, Sunnyvale, CA (US); Fernando SILVEIRA, Livermore, CA (US); Bo WANG, San Jose, CA (US); Yang YANG, Cupertino, CA (US); Kartik RAMASWAMY, San Jose, CA (US)

(21) Appl. No.: 18/662,017

(22) Filed: May 13, 2024

(51) Int. Cl. H01J 37/32; H01G 17/00

(52) U.S. Cl. CPC H01J 37/3211; H01G 17/00; H01J 37/32183; H01J 2237/3341

(57) ABSTRACT

An apparatus for generating plasma inductively in a process chamber is provided herein and comprises a closed-loop series inductor/capacitor (LC) coil network comprising a plurality of LC sections and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.

### FIELD

Embodiments of the present disclosure generally relate methods and apparatus for processing a substrate, and, for example, to methods and apparatus that use inductively coupled plasma resonator sources.

### BACKGROUND

Inductively coupled plasma (ICP) resonator sources are key technology to generate and control plasma for semiconductor's reactive ion etching (RIE) equipment. Traditionally, an ICP resonator source has a spiral or helical shape placed above or around the ICP resonator source's RIE chamber. By feeding a radio frequency (RF) current to an ICP resonator source, the ICP resonator source emits an electromagnetic (EM) wave that ignites and sustains plasma in the RIE chamber body, e.g., via inductive coupling. As can be appreciated, the design of an ICP resonator source determines the RIE equipment's plasma control performance.

Achieving one or more design targets, such as, low skew, easy plasma striking, high etching rate (ER), high electrical current, and/or low coil voltage, can often be difficult using conventional ICP resonator sources. Additionally, due to non-uniform power deposition, a single coil ICP resonator source inherently will result in an “m” shape plasma density and ER skew. To reduce the skew, conventional RIE equipment often use two ICP coils, e.g., coaxially arranged, which control a plasma's uniformity via the ICP coils' current ratio and phase. With such a design, however, a Faraday shield becomes necessary due to a high coil voltage, and the Faraday shield is detrimental to the ICP coils' plasma striking and overall ER. Hence, conventional ICP coils are not suitable for the future advanced semiconductor manufacturing that requires wide operation window, high ER, and low skew.

Accordingly, the inventors provide herein improved methods and apparatus that use inductively coupled plasma resonator sources.

### SUMMARY

In at least some embodiments, an apparatus for generating plasma inductively in a process chamber comprises a closed-loop series inductor/capacitor (LC) coil network comprising a plurality of LC sections and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.

In at least some embodiments, an apparatus for generating plasma inductively in a process chamber comprises a closed-loop series inductor/capacitor (LC) coil network operably coupled to a lid of the process chamber, comprising a plurality of LC sections, and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.

In at least some embodiments, an inductively coupled plasma (ICP) process chamber for treating substrates with plasma comprises the ICP process chamber having a chamber body with a lid, a process volume, and a substrate support. An RF power source can be configured to provide RF power to the ICP process chamber. A closed-loop series inductor/capacitor (LC) coil network comprises a plurality of LC sections and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.

Other and further embodiments are disclosed below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are thus not to be considered limiting of scope, for the disclosure may admit to other equally effective embodiments.

FIG. 1 is a cross-sectional view of an inductively coupled plasma (ICP) process chamber, in accordance with at least some embodiments of the present disclosure;

FIG. 2 is a diagram of a flower source with n sections, an equivalent circuit model of each of the n sections, and an equivalent circuit model of the flower source, in accordance with at least some embodiments of the present disclosure;

FIG. 3 is a diagram of a flower source with four LC sections and a diagram of a flower source with six LC sections, in accordance with at least some embodiments of the present disclosure;

FIG. 4 is a diagram of a flower source with capacitors disposed at an inside of the flower source and a diagram of a flower source with capacitors disposed at a middle of the flower source, in accordance with at least some embodiments of the present disclosure;

FIG. 5 is a diagram of various inductor shapes and equivalent circuits, in accordance with at least some embodiments of the present disclosure;

FIG. 6 is a schematic diagram of a flower source and top down view of flower source, in accordance with at least some embodiments of the present disclosure;

FIG. 7 is a schematic diagram of excitation driving of a flower source and a schematic diagram of excitation driving of a flower source using a tunable capacitor, in accordance with at least some embodiments of the present disclosure;

FIG. 8 is a schematic diagram of direct driving of a four-section flower source, in accordance with at least some embodiments of the present disclosure;

FIG. 9 is a schematic diagram of excitation driving of a flower source using a small helical coil, in accordance with at least some embodiments of the present disclosure;

FIG. 10 is a schematic diagram of excitation driving of a flower source using a medium helical coil, in accordance with at least some embodiments of the present disclosure;

FIG. 11 is a schematic diagram of excitation driving of a flower source using a large helical coil, in accordance with at least some embodiments of the present disclosure;

FIG. 12 is a schematic diagram of excitation driving of a flower source using a flower-shape excitation coil, in accordance with at least some embodiments of the present disclosure;

FIG. 13 is a schematic diagram of excitation driving of a flower source using a flower-shape excitation coil with less sections than the flower source below, in accordance with at least some embodiments of the present disclosure;

FIG. 14 is a schematic diagram of static EB-field enhanced setup with excitation driven flower source setup, in accordance with at least some embodiments of the present disclosure;

FIG. 15 is a schematic diagram of plasma/ER tuning using a flower source, in accordance with at least some embodiments of the present disclosure; and

FIG. 16 is a schematic diagram of plasma/ER tuning via two excitation coils, in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

As noted above, the inventors provide herein improved methods and apparatus that use inductively coupled plasma resonator sources (e.g., with a flower shape network). For example, in at least some embodiments, an apparatus for generating plasma inductively in a process chamber can comprise a closed-loop series inductor/capacitor (LC) coil network. The closed-loop series inductor/capacitor (LC) coil network can comprise a plurality of LC sections and has a resonant frequency defined by a total inductance and a capacitance of the plurality of LC sections. When RF power is applied to the closed-loop series inductor/capacitor (LC) coil network, a resonant electrical current is generated in the closed-loop series inductor/capacitor (LC) coil network to inductively generate and sustain plasma in the process chamber. The methods and apparatus described herein provide an improvement to conventional apparatus. For example, the methods and apparatus described herein use is a series LC network that ensures that current in all inductors is the same, which significantly improves the uniformity of plasma and RF power deposition. Additionally, compared to conventional apparatus, which typically operate at multiple frequencies, because of the series LC network, the resonator source can operate at a single resonant frequency, thus simplifying frequency control.

Reactive ion etching (RIE) is the most widely adopted plasma etching technique. RIE utilizes directional ion bombardment to enhance the surface etching reaction rate and to realize profile control. An RF ICP source is positioned on top of the reaction chamber. The ICP source generates mass reactive species and controls the plasma density and ion flux. The operation of the RF ICP source is to induce an RF current in the reaction chamber by flowing current into an adjacent coil. The coil structure becomes an integral part of ICP source.

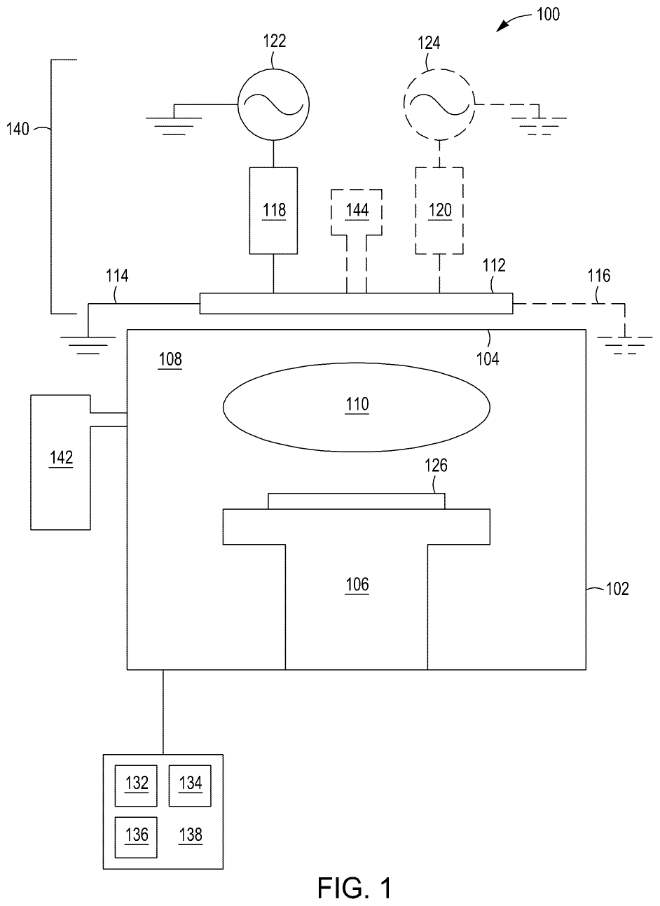

FIG. 1 is an example of an ICP process chamber 100. The embodiments of the present disclosure may be used with any type of ICP process chamber such as, but not limited to, RIE reactor chambers and the like. The ICP process chamber 100 has a chamber body 102 with a chamber lid 104, a process volume 108, a substrate support 106, and an ICP source 140. The ICP process chamber 100 may also have a gas supply 142 for providing process gases into the process volume 108. In some embodiments, the ICP process chamber 100 may also have a center-fed apparatus 144 that may be, but is not limited to, a center-fed gas supply and/or a center-fed remote plasma source (RPS) and the like.

The substrate support 106 provides a platform for holding a substrate 126 during processing in the process volume 108. Plasma 110 is inductively formed using the ICP source 140 which includes a radial coil network 112 and RF power sources. The radial coil network 112 of the present techniques is a planar coil structure that can be positioned directly above the chamber lid 104 of the ICP process chamber 100. In some embodiments, the radial coil network 112 may be connected to a first RF power source 122 via a first match network 118 and grounded via a first ground 114. In some embodiments, a second RF power source 124 may be optional and may be connected to the radial coil network 112 via a second RF match network 120 and grounded via a second ground 116. Any number of RF power sources and grounds may be implemented with the radial coil network 112.

A controller 138 controls the operation of any of the ICP process chamber aspects as described herein. The controller 138 may use a direct control of the ICP process chamber 100, or alternatively, by controlling the computers (or controllers) associated with the ICP process chamber 100. In operation, the controller 138 enables data collection and feedback from the ICP process chamber 100 and/or ICP source 140 to optimize performance of the ICP process chamber 100 and/or ICP source. The controller 138 generally includes a CPU 132 (central processing unit), a memory 134, and a support circuit 136. The CPU 132 may be any form of a general-purpose computer processor that can be used in an industrial setting. The support circuit 136 is conventionally coupled to the CPU 132 and may comprise a cache, clock circuits, input/output subsystems, power supplies, and the like. Software routines, such as methods and aspects of operation of the apparatus including the radial coil network 112 as described herein may be stored in the memory 134 and, when executed by the CPU 1322, transform the CPU 132 into a specific purpose computer (a controller 138). The software routines may also be stored and/or executed by a second controller (not shown) that is located remotely from the ICP process chamber 100.

The memory 134 is in the form of computer-readable storage media that contains instructions, when executed by the CPU 132, to facilitate the operation of the semiconductor processes and ICP source 140 including the radial coil network 112. The instructions in the memory 134 are in the form of a program product such as a program that implements operational aspects of the present disclosure such as phase shift/skewing control of the radial coil network 112 and the like. The program code may conform to any one of a number of different programming languages. In one example, the disclosure may be implemented as a program product stored on a computer-readable storage media for use with a computer system. The program(s) of the program product define functions of the aspects (including the operation processes and control described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present disclosure.

As noted above, the inventors describe herein an ICP resonator source. In at least some embodiments, the ICP resonator source comprises a closed-loop series inductor/capacitor (LC) coil network (e.g., with a generally flower shape) that can comprise a plurality of LC sections and can have a resonant frequency defined by a total inductance and a capacitance of the plurality of LC sections. As the closed-loop series inductor/capacitor (LC) coil network does not use the, typical, m-shape, the closed-loop series inductor/capacitor (LC) coil network provides a relatively high ER without the need for a Faraday shield, e.g., due to the closed-loop series inductor/capacitor (LC) coil network resonant electric network, which enables high resonant current with a low coil voltage. For example, when RF power is applied to the closed-loop series inductor/capacitor (LC) coil network, a resonant electrical current is generated in the closed-loop series inductor/capacitor (LC) coil network to inductively generate and sustain plasma in the process chamber.

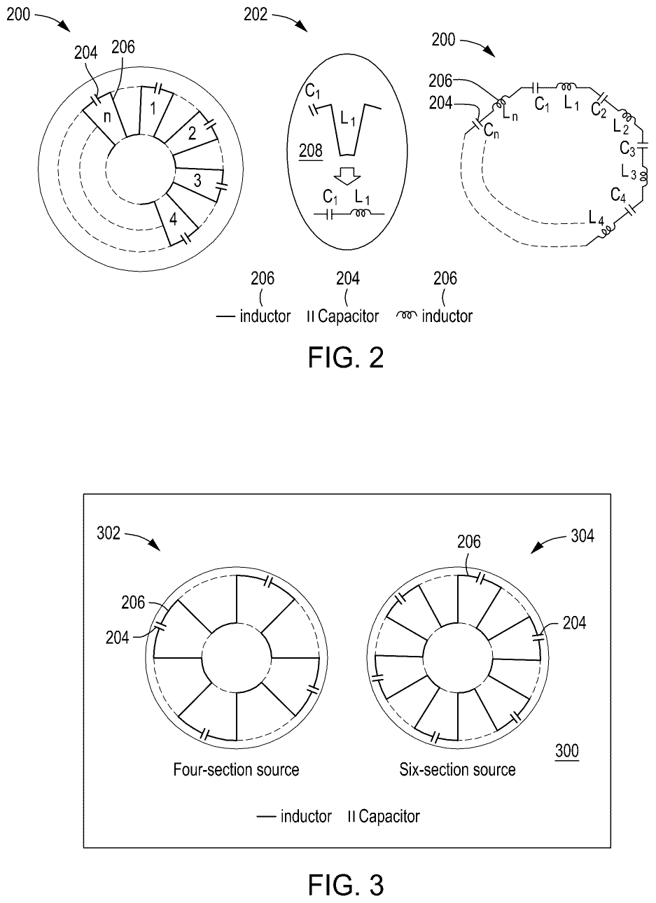

FIG. 2 is a diagram of a flower source with n sections, an equivalent circuit model of each of the n sections, and an equivalent circuit model of the flower source, in accordance with at least some embodiments of the present disclosure. For example, FIG. 2 depicts a generalized embodiment of the closed-loop series inductor/capacitor (LC) coil network 200 along with the closed-loop series inductor/capacitor (LC) coil network 200 equivalent circuit model 202. As shown in FIG. 2, the closed-loop series inductor/capacitor (LC) coil network 200 can comprise n capacitors 204 connected by n inductors 206 (e.g., n=1, 2, 3, . . . ) to form a generally flower-like series network. Each LC section 208 of the closed-loop series inductor/capacitor (LC) coil network 200 is equivalent to a series LC section with an inductance of Lᵢ and a capacitance of Cᵢ, and connecting all the LC sections together forms the closed-loop series inductor/capacitor (LC) coil network 200, which has a resonant frequency defined by Equation 1 below,

$$f = \frac{{\sum }_{1}^{n} {C}_{i}^{- 1}}{2 π {\sum }_{1}^{n} {L}_{i}} . \qquad ( 1 )$$

With an appropriate driving method using RF power at a frequency close to f, a resonant electrical current can be generated in the loop and emit electromagnetic (EM) waves to strike and sustain a plasma.

In at least some embodiments, the closed-loop series inductor/capacitor (LC) coil network 200 can have any number of sections n, which can be an integer greater than or equal to 1. For example, FIG. 3 is a diagram 300 of the closed-loop series inductor/capacitor (LC) coil network 200 (e.g., a flower source) with four LC sections 302 and the closed-loop series inductor/capacitor (LC) coil network 200 with six LC sections 304. In at least some embodiments, when the closed-loop series inductor/capacitor (LC) coil network 200 comprises the four LC sections 302, the four LC sections 302 can be disposed 90° apart. Similarly, when the closed-loop series inductor/capacitor (LC) coil network 200 comprises the six LC sections 304, the six LC sections 304 can be disposed 60° apart.

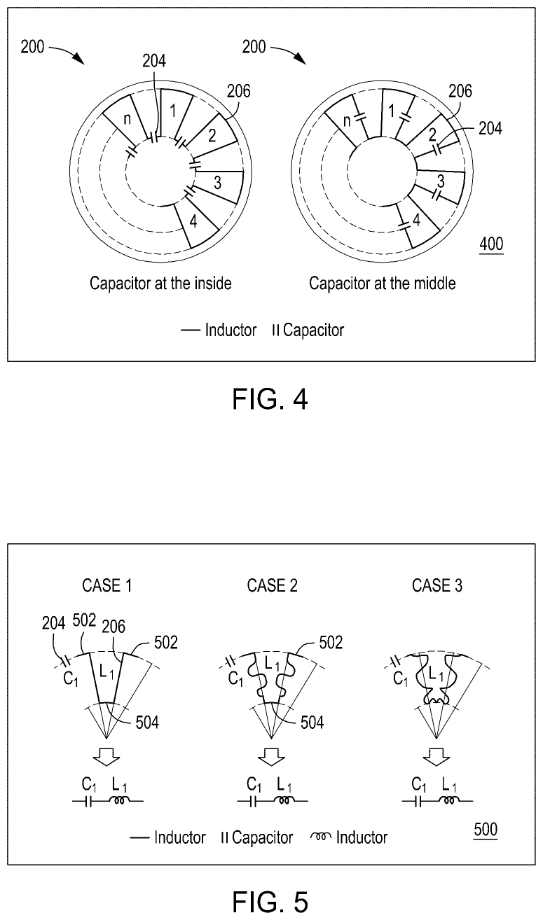

In at least some embodiments, the location of the capacitors 204 can be anywhere along the inductor 206. For example, FIG. 4 is a diagram 400 of the closed-loop series inductor/capacitor (LC) coil network 200 (e.g., a flower source). In at least some embodiments, the capacitors 204 can be disposed at an inside of the closed-loop series inductor/capacitor (LC) coil network 200. Similarly, in at least some embodiments, the capacitors 204 can be disposed at a middle of the closed-loop series inductor/capacitor (LC) coil network 200. Likewise, in at least some embodiments, the capacitors 204 can be disposed at an outside of the closed-loop series inductor/capacitor (LC) coil network 200 (see FIG. 3, for example).

In at least some embodiments, the shape of the inductors can be any one of continuous curves/lines that connects two neighboring capacitors. For example, FIG. 5 is a diagram 500 of various inductor shapes and equivalent circuits. For example, FIG. 5 shows each LC section having two outer arcs 502 with a radius of rₒᵤₜₑᵣ and one inner arc 504 with a radius of rᵢₙₙₑᵣ, which have two generally straight radial lines (e.g., a straight configuration) for connections (see case one). In at least some embodiments, the two outer arcs 502 and one inner arc 504 can be connected by two curved inductor sections (e.g., a curved configuration, see case two). In at least some embodiments, the LC sections can comprise no arcs but have a complex curved inductor, which can be located between rₒᵤₜₑᵣ and rᵢₙₙₑᵣ (see case three).

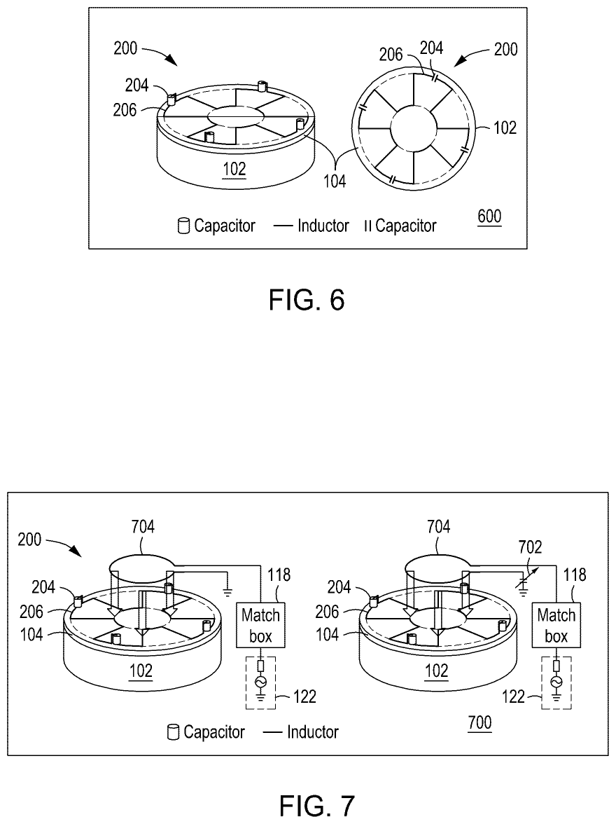

The closed-loop series inductor/capacitor (LC) coil network 200 can be disposed at various locations on the ICP process chamber 100 (e.g., on RIE equipment) for operation. For example, FIG. 6 is a schematic diagram 600 of the closed-loop series inductor/capacitor (LC) coil network 200 and top down view of the closed-loop series inductor/capacitor (LC) coil network 200. As shown in FIG. 6, in at least some embodiments, the closed-loop series inductor/capacitor (LC) coil network 200 can be disposed on the chamber lid 104. In such embodiments, no Faraday shield is required (but can be used) and rₒᵤₜₑᵣ can be smaller than the radius of the chamber lid 104. The chamber lid 104 material (e.g., beneath the closed-loop series inductor/capacitor (LC) coil network 200) can be made from material that allows EM to pass through the chamber lid 104. In at least some embodiments, the chamber lid 104 can be made from non-metals. Alternatively, the closed-loop series inductor/capacitor (LC) coil network 200 can be disposed above the chamber lid 104, with a uniform gap between the chamber lid 104 and the closed-loop series inductor/capacitor (LC) coil network 200. Such a configuration can increase the closed-loop series inductor/capacitor (LC) coil network 200 from frequency f to f_{source+chamber}, e.g., due to the ICP process chamber 100 to the closed-loop series inductor/capacitor (LC) coil network 200 coupling effect. Similarly, when plasma is present in the chamber body 102, the resonant frequency of the closed-loop series inductor/capacitor (LC) coil network 200 changes to f_{source+chamber+plasma} due to coupling effect between the ICP process chamber 100, the closed-loop series inductor/capacitor (LC) coil network 200, and the plasma.

The closed-loop series inductor/capacitor (LC) coil network 200 driving method can be either excitation driving or direct driving. FIG. 7 is a schematic diagram 700 of excitation driving of the closed-loop series inductor/capacitor (LC) coil network 200 and a schematic diagram of excitation driving of the closed-loop series inductor/capacitor (LC) coil network 200 using a tunable capacitor 702. For example, an excitation coil 704 can be disposed above the closed-loop series inductor/capacitor (LC) coil network 200. In such embodiments, the closed-loop series inductor/capacitor (LC) coil network 200 can have one node grounded and the other node connected to an RF match box (e.g., the first match network 118). When an RF source (e.g., the first RF power source 122) supplies RF power to the excitation coil 704, an electromagnetic field (EB-field) emitted from the excitation coil 704 excites the closed-loop series inductor/capacitor (LC) coil network 200 below to generate an induced current. The current then emits EB-field to the chamber body 102 below the closed-loop series inductor/capacitor (LC) coil network 200, striking and sustaining plasma. In at least some embodiments, the tunable capacitor 702 (optional) can connect to the excitation coil 704 to tune the excitation coil's current and voltage. When the RF source frequency is close to f_{source+chamber+plasma}, induced current in the closed-loop series inductor/capacitor (LC) coil network 200 can be maximized while the closed-loop series inductor/capacitor (LC) coil network's voltage drops to a minimum at a given RF power. With proper configurations of the excitation coil 704 and a proper control, via the controller 138, of the electromagnetic coupling between the excitation coil 704 and the closed-loop series inductor/capacitor (LC) coil network 200, the induced current can be much higher than the current in excitation coil 704, as described in greater detail below. Therefore, at a given power, the closed-loop series inductor/capacitor (LC) coil network 200 can have a much lower source coil voltage when compared to conventional ICP sources, thus minimizing the risk of lid sputtering and requiring no Faraday shield to be present.

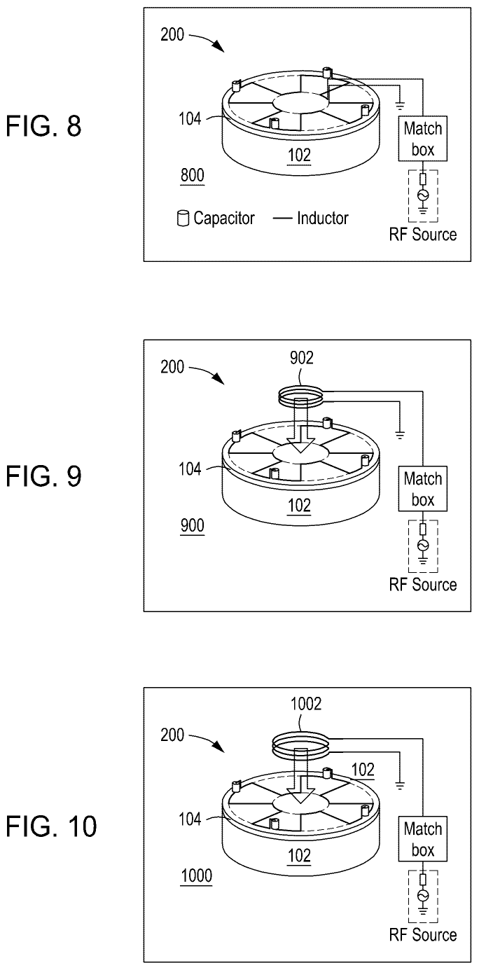

FIG. 8 is a schematic diagram 800 of direct driving of the closed-loop series inductor/capacitor (LC) coil network 200 with the four LC sections 302, in accordance with at least some embodiments of the present disclosure. In such embodiments, the closed-loop series inductor/capacitor (LC) coil network 200 can have one node (e.g., a source node) connected to ground and the other node connected to the RF match box (e.g., the first match network 118).

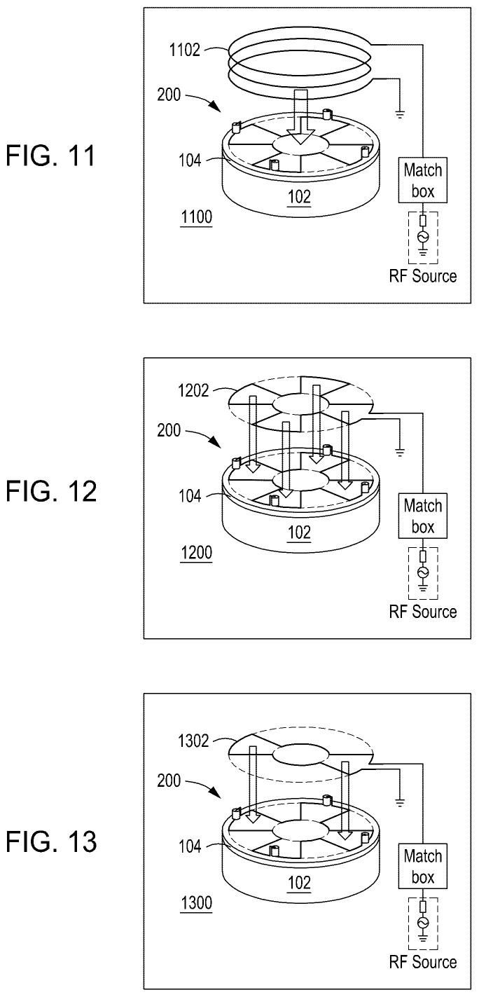

As noted above, with proper configurations of the excitation coil 704 and a proper control, via the controller 138, of the electromagnetic coupling between the excitation coil 704 and the closed-loop series inductor/capacitor (LC) coil network 200, the induced current can be much higher than the current in excitation coil 704. For example, the excitation coil 704 can have distinctive designs via changing coil shape, size, and setup height to control the excitation coil 704 electromagnetic coupling to the closed-loop series inductor/capacitor (LC) coil network 200. Accordingly, FIG. 9 is a schematic diagram 900 of excitation driving of the closed-loop series inductor/capacitor (LC) coil network 200 using a relatively small helical coil (e.g., having an outer diameter that is less than an inner diameter of the closed-loop series inductor/capacitor (LC) coil network 200), in accordance with at least some embodiments of the present disclosure. For example, FIG. 9 shows a helical coil 902 with diameter d and coaxially placed (e.g., a coaxial configuration) above the closed-loop series inductor/capacitor (LC) coil network 200 at a height of h. The diameter d and the height h are two design variables to control excitation coil 704 electromagnetic coupling to the closed-loop series inductor/capacitor (LC) coil network 200 coupling. FIG. 10 is a schematic diagram 1000 of excitation driving of the closed-loop series inductor/capacitor (LC) coil network 200 using a relatively medium helical coil 1002 (e.g., having an outer diameter that is equal to the inner diameter of the closed-loop series inductor/capacitor (LC) coil network 200), and FIG. 11 is a schematic diagram 1100 of excitation driving of the closed-loop series inductor/capacitor (LC) coil network 200 using a relatively a large helical coil 1102 (e.g., having an outer diameter that is greater than the inner diameter of the closed-loop series inductor/capacitor (LC) coil network. FIG. 12 is a schematic diagram 1200 of excitation driving of the closed-loop series inductor/capacitor (LC) coil network 200 using another one of the closed-loop series inductor/capacitor (LC) coil network 1202, in accordance with at least some embodiments of the present disclosure. In such embodiments, the another one of the closed-loop series inductor/capacitor (LC) coil network 1202 has the same general configuration and a same amount of LC sections as the closed-loop series inductor/capacitor (LC) coil network 200. Alternatively, the another one of the closed-loop series inductor/capacitor (LC) coil network 1302 has the same general configuration and a different amount of LC sections as the closed-loop series inductor/capacitor (LC) coil network 200.

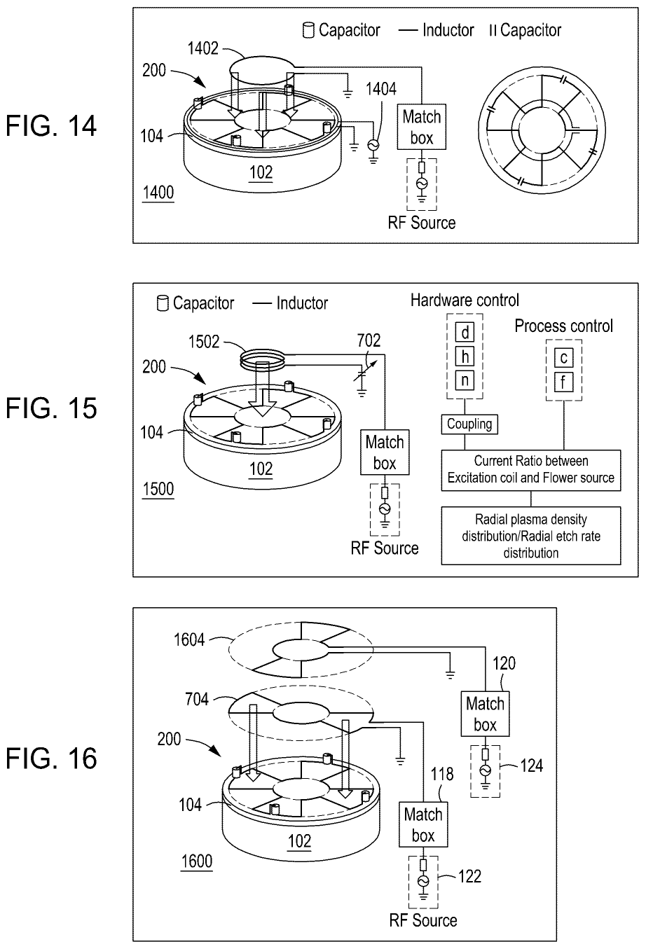

The closed-loop series inductor/capacitor (LC) coil network 200 can work/operate with a static excitation coil (e.g., static EB-field coil) to enhance source to plasma coupling and etch rate (ER). For example, FIG. 14 is a schematic diagram 1400 of static EB-field enhanced setup with excitation driven closed-loop series inductor/capacitor (LC) coil network 200, in accordance with at least some embodiments of the present disclosure. For example, the static EB-field coil can be placed outside the closed-loop series inductor/capacitor (LC) coil network 200 and connected to a DC bias 1404. The static EB-field coil can generate a static magnetic field (EB-field), e.g., perpendicular to the chamber lid 104. In such embodiments, an additional EB-field can confine electrons when plasma is present in the chamber body 102, thus enhancing electron to gas collision and helping the closed-loop series inductor/capacitor (LC) coil network 200 to generate denser plasma than the closed-loop series inductor/capacitor (LC) coil network 200 alone.

The closed-loop series inductor/capacitor (LC) coil network 200 can be configured to tune plasma density distribution and radial ER distribution via current ration control in the excitation coil 704 and the closed-loop series inductor/capacitor (LC) coil network 200 source parameters. For example, FIG. 15 is a schematic diagram 1500 of plasma/ER tuning using the closed-loop series inductor/capacitor (LC) coil network 200, in accordance with at least some embodiments of the present disclosure. For example, plasma/ER tuning can be achieved by hardware parameter control and process parameter control. For example, the hardware parameters can include, but are not limited to, excitation coil size (d), number of coil turns (n), and/or a vertical distance (h) between the excitation coil 704 and the closed-loop series inductor/capacitor (LC) coil network 200. The hardware parameters can change electromagnetic coupling between the excitation coil 704 and the closed-loop series inductor/capacitor (LC) coil network 200, thus changing a current ratio between the excitation coil 704 and the closed-loop series inductor/capacitor (LC) coil network 200. Similarly, the process control can be achieved through a tunable capacitor (e.g., the tunable capacitor 702 connected to excitation coil 704 and the output frequency of RF source. Changing the tunable capacitor's capacitance (C) or changing the RF source frequency (f), can change an impedance ratio between the excitation coil side and the closed-loop series inductor/capacitor (LC) coil network source side, thus changing a current ratio between excitation coil and the closed-loop series inductor/capacitor (LC) coil network. Accordingly, tuning plasma distribution in the ICP process chamber 100, as well as radial ER distribution, can be achieved via one or more of the current ratio control methods.

In at least some embodiments, one or more additional excitation coils can be used to further improve the excitation coils' tunability for plasma and ER distribution. For example, FIG. 16 is a schematic diagram 1600 of plasma/ER tuning via two excitation coils, in accordance with at least some embodiments of the present disclosure. For example, a second excitation coil 1602 can be disposed above and orthogonal to the excitation coil 704 and the closed-loop series inductor/capacitor (LC) coil network. In such embodiments, the second excitation coil 1602 can be connected to the RF match (e.g., the second RF match network 120) and the second RF power source 124 to induce the electromagnetic field in the closed-loop series inductor/capacitor (LC) coil network 200. As varying an RF source frequency can change ER/plasma distribution, one can set the two RF sources with different frequencies and control RF sources' on-and-off time and interval to control ER distribution.

While the foregoing is directed to embodiments of the present disclosure, other and further embodiments of the disclosure may be devised without departing from the basic scope thereof.

1. An apparatus for generating plasma inductively in a process chamber, comprising:
a closed-loop series inductor/capacitor (LC) coil network comprising a plurality of LC sections and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.

2. The apparatus of claim 1, wherein the closed-loop series inductor/capacitor (LC) coil network comprises one of four LC sections or six LC sections.

3. The apparatus of claim 2, wherein the four LC sections are disposed 90° apart and the six LC sections are disposed 60° apart.

4. The apparatus of claim 1, wherein capacitors of the LC sections are located at at least one of an inside of the closed-loop series inductor/capacitor (LC) coil network, a middle of the closed-loop series inductor/capacitor (LC) coil network, or an outside of the closed-loop series inductor/capacitor (LC) coil network.

5. The apparatus of claim 1, wherein inductors of the LC sections have at least a straight configuration or a curved configuration.

6. The apparatus of claim 1, wherein the closed-loop series inductor/capacitor (LC) coil network is disposed one of on a lid of the process chamber or above the lid of the process chamber.

7. The apparatus of claim 6, wherein the closed-loop series inductor/capacitor (LC) coil network has an outer diameter that is less than an outer diameter of the lid.

8. The apparatus of claim 6, wherein when the closed-loop series inductor/capacitor (LC) coil network is disposed on the lid of the process chamber, material of the lid beneath the closed-loop series inductor/capacitor (LC) coil network is made from non-metal.

9. The apparatus of claim 1, wherein when the closed-loop series inductor/capacitor (LC) coil network is disposed above a lid of the process chamber, a uniform gap is present between the lid and the closed-loop series inductor/capacitor (LC) coil network.

10. The apparatus of claim 1, wherein the closed-loop series inductor/capacitor (LC) coil network is driven by at least one of excitation driving or direct driving.

11. The apparatus of claim 10, wherein, when the closed-loop series inductor/capacitor (LC) coil network is driven by excitation driving, the apparatus further comprises an excitation coil disposed above the closed-loop series inductor/capacitor (LC) coil network and connected to an RF match of an RF power source to induce an electromagnetic field in the closed-loop series inductor/capacitor (LC) coil network.

12. The apparatus of claim 11, further comprising a tunable capacitor coupled between the excitation coil and ground, wherein the tunable capacitor is configured to tune a current and a voltage of the excitation coil.

13. The apparatus of claim 11, wherein the excitation coil has a coaxial configuration.

14. The apparatus of claim 11, wherein the excitation coil has an outer diameter that is one of less than an inner diameter of the closed-loop series inductor/capacitor (LC) coil network, equal to the inner diameter of the closed-loop series inductor/capacitor (LC) coil network, or greater than the inner diameter of the closed-loop series inductor/capacitor (LC) coil network.

15. The apparatus of claim 11, wherein the excitation coil has a same general configuration and a same amount of LC sections as the closed-loop series inductor/capacitor (LC) coil network.

16. The apparatus of claim 11, wherein the excitation coil has a same general configuration and a different amount of LC sections as the closed-loop series inductor/capacitor (LC) coil network.

17. The apparatus of claim 11, further comprising a second excitation coil disposed above and orthogonal to the excitation coil and the closed-loop series inductor/capacitor (LC) coil network and connected to the RF match of the RF power source to induce the electromagnetic field in the closed-loop series inductor/capacitor (LC) coil network.

18. The apparatus of claim 10, wherein, when the closed-loop series inductor/capacitor (LC) coil network is driven by direct driving, a first node of the closed-loop series inductor/capacitor (LC) coil network is connected to an RF match of an RF power source and a second node of the closed-loop series inductor/capacitor (LC) coil network is connected to ground.

19. An apparatus for generating plasma inductively in a process chamber, comprising:
a closed-loop series inductor/capacitor (LC) coil network operably coupled to a lid of the process chamber, comprising a plurality of LC sections, and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.

20. An inductively coupled plasma (ICP) process chamber for treating substrates with plasma, comprising:
the ICP process chamber has a chamber body with a lid, a process volume, and a substrate support;
an RF power source configured to provide RF power to the ICP process chamber; and
a closed-loop series inductor/capacitor (LC) coil network comprising a plurality of LC sections and having a resonant frequency defined by a total inductance and a capacitance of the plurality of LC sections such that when RF power is applied to the closed-loop series inductor/capacitor (LC) coil network a resonant electrical current is generated in the closed-loop series inductor/capacitor (LC) coil network to inductively generate and sustain plasma in the process chamber.
